(19) United States
(12) Patent Application Publication
(10) Pub. No.: US 2026/0136767 A1
(43) Pub. Date: May 14, 2026

(54) THIN FILM TRANSISTOR SUBSTRATE AND DISPLAY DEVICE USING THE SAME

(71) Applicant: LG Display Co., Ltd., Seoul (KR)

(72) Inventors: Dohyung Lee, Paju-si (KR); JuHeyuck Baeck, Paju-si (KR); GaWon Yang, Paju-si (KR)

(73) Assignee: LG Display Co., Ltd., Seoul (KR)

(21) Appl. No.: 19/343,779

(22) Filed: Sep. 29, 2025

(30) Foreign Application Priority Data
Nov. 14, 2024 (KR) 10-2024-0161947

(51) Int. Cl. H10K 59/121

(52) U.S. Cl. CPC H10K 59/1213

(57) ABSTRACT

A thin film transistor substrate including a substrate; an active layer on the substrate; a gate electrode overlapping the active layer; a first sub gate electrode electrically connected to the gate electrode and overlapping the active layer at one side of the gate electrode in plain view; and a second sub gate electrode electrically connected to the gate electrode and overlapping the active layer at an other side of the gate electrode in plan view. Further, the one side of the gate electrode opposed the other side opposing the one side of the gate electrode in plan view, and the first sub gate electrode and the second sub gate electrode are spaced apart from the active layer..

### CROSS-REFERENCE TO RELATED APPLICATION

This application claims priority to Korean Patent Application No. 10-2024-0161947, filed in the Republic of Korea on November 14, 2024, which is hereby incorporated by reference in its entirety.

### BACKGROUND

### Field of Technology

The present disclosure relates to a thin film transistor substrate and a display device using the same.

### Discussion of the Related Art

With the development of the information society, the demand for display devices for displaying images increases. Accordingly, various display devices such as liquid crystal display (LCD), plasma display panel (PDP), and organic light emitting display (OLED) are currently being used.

Among display devices, organic light emitting display (OLED) devices are self-luminous, and have superior viewing angles and contrast ratios compared to liquid crystal displays (LCD). In addition, organic light emitting display (OLED) devices do not require a separate backlight, making them lightweight and thin, and have the advantage of low power consumption. Still further, organic light emitting display (OLED) devices can be driven by low direct current voltage, have a fast response speed, and have the advantage of low manufacturing costs.

Thin film transistors, which can be used to drive the light emitting elements of organic light emitting display (OLED) devices, can be classified into amorphous silicon thin film transistors in which amorphous silicon is used as the active layer, polycrystalline silicon thin film transistors in which polycrystalline silicon is used as the active layer, and oxide semiconductor thin film transistors in which oxide semiconductor is used as the active layer, based on the material constituting the active layer. Among these different types of thin film transistors, oxide semiconductor thin film transistors have the advantage of high mobility and can exhibit large resistance variation depending on oxygen content, making it easy to obtain desired physical property. Furthermore, since the oxide constituting the active layer can be formed at a relatively low temperature during the manufacturing process, manufacturing costs are low. Also, due to the nature of oxides, oxide semiconductors are transparent, making them advantageous for implementing transparent displays.

Among the thin film transistors disposed in OLED driving circuits, some thin film transistors have a high voltage constantly applied to the source electrode or drain electrode. This can cause the device characteristic to deteriorate by applying an excessive voltage to the channel region when the thin film transistor is not driven, thereby lowering the on-current characteristic and shifting the threshold voltage (Vth) in the positive (+) direction. Therefore, it is important to develop a thin film transistor that has a voltage that is constantly applied to the thin film transistor disposed in the driving circuit or that does not deteriorate the device characteristic despite the application of a high voltage.

### SUMMARY OF THE DISCLOSURE

The present disclosure is designed to solve the above-mentioned problem, and its purpose is to provide a thin film transistor substrate and a display device using the same, which relatively lowers the magnitude of the voltage distributed and applied to the channel part when not driven and does not deteriorate the on-current characteristic when driven. In order to achieve the above object, the present disclosure provides a thin film transistor substrate and a display device using the same, comprising a substrate, an active layer on the substrate, a gate electrode on the active layer, and a first sub gate electrode and a second sub gate electrode disposed on the active layer and disposed on one side of the gate electrode, wherein the first sub gate electrode overlaps one side of the active layer and is spaced apart from the other side of the active layer in a planar view, and wherein the second sub gate electrode overlaps the other side of the active layer and is spaced apart from the one side of the active layer in the planar view.

### BRIEF DESCRIPTION OF THE DRAWINGS

The above and other objects, features, and other advantages of the present disclosure will be more clearly understood from the following detailed description taken in conjunction with the accompanying drawings, in which:

FIG. 1 is a schematic perspective view of a display device according to one embodiment of the present disclosure;

FIG. 2 is a plan view schematically showing a display device according to one embodiment of the present disclosure;

FIG. 3 is a plan view of a thin film transistor substrate according to one embodiment of the present disclosure;

FIGS. 4A and 4B are schematic plan views of a thin film transistor substrate according to one embodiment of the present disclosure. In this instance, FIGS. 4A and 4B relate to FIG. 3;

FIG. 5 is a cross-sectional view of a thin film transistor substrate according to one embodiment of the present disclosure. In this instance, FIG. 5 relates to cross-section I-I' of FIG. 3;

FIG. 6 is a cross-sectional view of a thin film transistor substrate according to another embodiment of the present disclosure. In this instance, FIG. 6 relates to cross-section I-I' of FIG. 3;

FIG. 7A is a plan view of a thin film transistor substrate according to another embodiment of the present disclosure, and FIG. 7B is a schematic plan view of a thin film transistor substrate according to another embodiment of the present disclosure;

FIG. 8 is a cross-sectional view of a thin film transistor substrate according to another embodiment of the present disclosure. In this instance, FIG. 8 is taken along section II-II' of FIG. 7A;

FIG. 9A is a plan view of a thin film transistor substrate according to another embodiment of the present disclosure, and FIG. 9B is a schematic plan view of a thin film transistor substrate according to another embodiment of the present disclosure;

FIG. 10 is a cross-sectional view of a thin film transistor substrate according to another embodiment of the present disclosure. In this instance, FIG. 10 is taken along section III-III' of FIG. 9A;

FIG. 11 is a plan view of a thin film transistor substrate according to another embodiment of the present disclosure;

FIG. 12 is a plan view of a thin film transistor substrate according to another embodiment of the present disclosure;

FIG. 13 is a cross-sectional view of a display device including a thin film transistor substrate according to one embodiment of the present disclosure; and

FIG. 14 is a circuit diagram of a shift register according to one embodiment of the present disclosure.

### DETAILED DESCRIPTION OF THE EMBODIMENTS

The advantages and features of the present disclosure, and the methods for achieving them, will become clear with reference to the embodiments described in detail below together with the accompanying drawings. However, the present disclosure is not limited to the embodiments disclosed below, but can be implemented in various different forms, and these embodiments are provided only to make the disclosure of the present disclosure complete and to fully inform a person having ordinary skill in the art to which the present disclosure belongs of the scope of the present disclosure, and the present disclosure is defined only by the scope of the claims.

The shapes, sizes, ratios, angles, numbers, or the like. disclosed in the drawings for explaining embodiments of the present disclosure are exemplary, and therefore the present disclosure is not limited to the matters illustrated. Like reference numerals refer to like elements throughout the specification. In addition, in describing the present disclosure, if it is determined that a detailed description of a related known technology can unnecessarily obscure the gist of the present disclosure, the detailed description will be omitted. When the terms “includes,” “has,” “consists of,” or the like, are used in this specification, other parts can be added unless “only” is used. When a component is expressed in the singular, it includes a case where the plural is included unless there is a specifically explicit description.

When interpreting a component, it is interpreted as including the error range even if there is no separate explicit description. When describing a positional relationship, for example, when the positional relationship between two parts is described as “on.” “upper,” “lower,” “next to,” or the like, one or more other parts can be located between the two parts, unless “right” or “directly” is used. When describing a temporal relationship, for example, when describing a temporal relationship using phrases such as “after,” “following,” “next to,” before,” it can also include cases where there is no continuity, as long as “right away” or “directly” is not used.

Although the terms first, second, or the like, are used to describe various components, these components are not limited by these terms. These terms are only used to distinguish one component from another. Accordingly, a first component referred to below can also be a second component within the technical concept of the present disclosure.

The individual features of the various embodiments of the present disclosure can be partially or wholly combined or combined with each other, and can be technically linked and driven in various ways, and each embodiment can be implemented independently of each other or can be implemented together in a related relationship. Hereinafter, embodiments of the present disclosure will be described in detail with reference to the drawings.

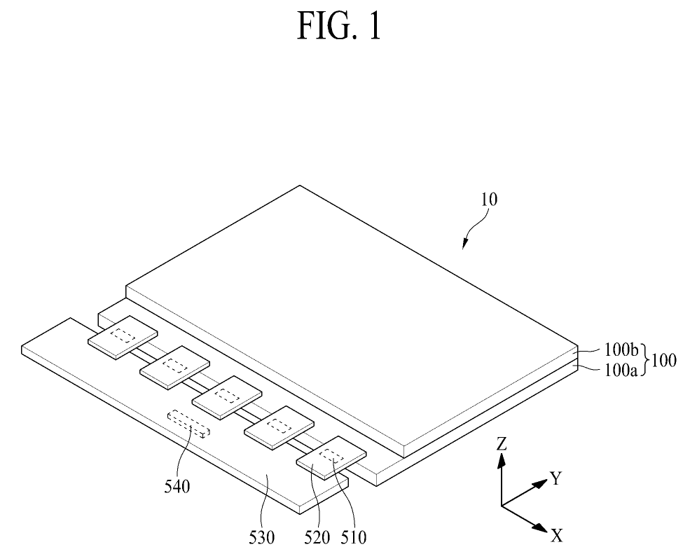

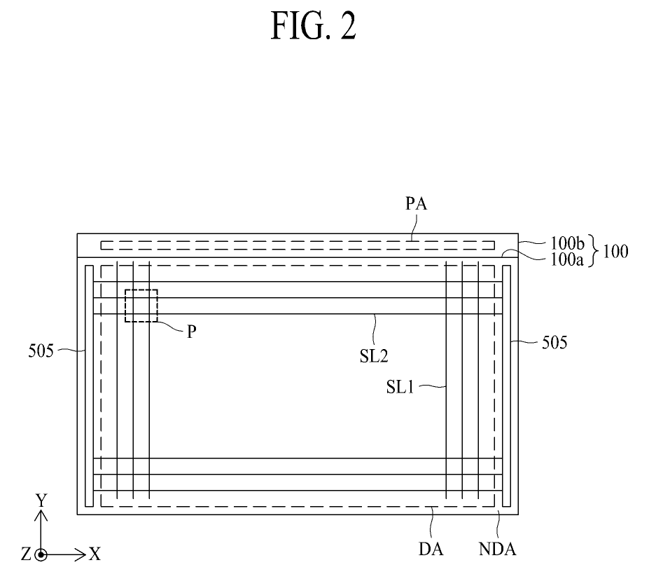

FIG. 1 is a schematic perspective view of a display device according to one embodiment of the present disclosure. FIG. 2 is a plan view schematically showing a display device according to one embodiment of the present disclosure. Hereinafter, the X-axis represents the direction parallel to gate lines, the Y-axis represents the direction parallel to data lines, and the Z-axis represents the height (or thickness) direction of the display device 10. The display device 10 according to one embodiment of the present disclosure has been described with a focus on being implemented as an organic light emitting diode (OLED) display, but can also be implemented as a liquid crystal display, a plasma display panel (PDP), a quantum dot light emitting display (QLED), or an electrophoresis display.

Referring to FIGS. 1 and 2, a display device 10 according to one embodiment of the present disclosure includes a display panel 100, a source drive integrated circuit (hereinafter referred to as “IC”) 510, a flexible film 520, a circuit board 530, and a timing control unit 540. The display panel 100 includes the first substrate 100a and the second substrate 100b facing each other. The second substrate 100b can be an encapsulation substrate. The first substrate 100a can be a plastic film, a glass substrate, or a silicon wafer substrate formed using a semiconductor process while the second substrate 100b can be a plastic film, a glass substrate, or an encapsulation film. The first substrate 100a and the second substrate 100b can be made of a transparent material. Further, as shown in FIG. 2, the display panel 100 can be divided into a display area DA where pixels are formed to display an image and a non-display area NDA where no image is displayed.

As also shown in FIG. 2, the display area DA can be provided with a plurality of vertical signal lines SL1, a plurality of horizontal signal lines SL2, and a plurality of pixels P, and the non-display area NDA can be provided with a pad area PA in which pads are arranged and at least one gate driver 505. Further, FIG. 2 illustrates a state in which one gate driver 505 is disposed on each (left and right) side of the display panel 100, but the present disclosure is not limited thereto. Also, the plurality of vertical signal lines SL1 can extend in a first direction (e.g., Y-axis direction) and can intersect the plurality of horizontal signal lines SL2 in the display area DA. The plurality of vertical signal lines SL1 can be, for example, a high potential voltage line supplying a high potential voltage to an anode electrode, a reference voltage line transmitting a reference signal to each of the plurality of pixels P, a data line transmitting a data signal to each of the plurality of pixels P, or the like., but are not limited thereto, and depending on the level of technology in the art, the plurality of vertical signal lines SL1 can be one of various wirings transmitting signals.

Also, the plurality of horizontal signal lines SL2 can extend in a second direction (e.g., X-axis direction) in the display area DA. In the present example, the plurality of horizontal signal lines SL2 can be, for example, gate lines that transmit gate signals to each of the plurality of pixels P, but are not limited thereto, and depending on the level of technology in the art, the plurality of horizontal signal lines SL2 can be one of various wirings that transmit signals. The plurality of pixels P, which are configured to emit a predetermined amount of light to display an image, are disposed in an area where the plurality of first signal lines SL1 are disposed or in an area where the plurality of first signal lines SL1 and the plurality of second signal lines SL2 intersect.

In operation, the source drive IC 510 receives digital video data and a source control signal from the timing control unit 540. The source drive IC 510 then converts digital video data into analog data voltages according to the source control signal and supplies the converted data to a data line. When the source drive IC 510 is manufactured as a driving chip, the source drive IC 510 can be mounted on the flexible film 520 in a COF (chip on film) or COP (chip on plastic) method.

Also, the wires connecting pads and the source drive IC 510, and wires connecting pads and wires of the circuit board 530 can be attached to, and formed on, the flexible film 520. The flexible film 520, in turn, can be attached onto the pads using an anisotropic conducting film, thereby connecting the pads and the wires of the flexible film 520. In addition, the circuit board 530 can have a plurality of circuits implemented with driving chips mounted thereon. For example, the timing control unit 540 can be mounted on the circuit board 530. In various embodiments, the circuit board 530 can be a printed circuit board or a flexible printed circuit board.

In operation, the timing control unit 540 receives digital video data and a timing signal from an external system board. Next, the timing control unit 540 generates a gate control signal for controlling the operation timing of the gate driver based on the timing signal and a source control signal for controlling the source drive ICs 510. Then, the timing control unit 540 supplies the gate control signal to the gate driver 505 and supplies the source control signal to the source drive ICs 510.

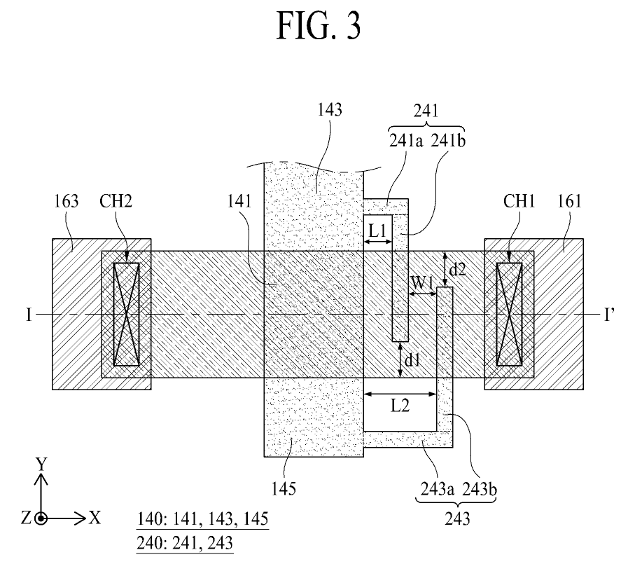

Next, FIG. 3 is a plan view of a thin film transistor substrate according to one embodiment of the present disclosure. As can be seen in FIG. 3, a thin film transistor substrate according to one embodiment of the present disclosure includes an active layer 120, a gate electrode 140, a first sub gate electrode 240, a source electrode 161, and a drain electrode 163.

The active layer 120 can extend along a first direction X, for example, a horizontal direction. The gate electrode 140 can extend in a second direction Y, for example, in the vertical direction and can overlap a portion of the active layer 120. As also shown in FIG. 3, the gate electrode 140 can include a first portion 141, a second portion 143, and a third portion 143. The first portion 141 can be defined as a portion of the gate electrode 140 that overlaps the active layer 120. The second portion 143 can be defined as another portion of the gate electrode 140 disposed on one side, for example, the upper side, of the first portion 141, while the third portion 145 can be defined as another portion of the gate electrode 140 disposed on the other side, for example, the lower side, of the first portion 141.

Further, the second portion 143 and the third portion 145 can be disposed to face each other with respect to the first portion 141, and each of the second portion 143 and the third portion 145 may not overlap with the active layer 120. Also, at least two first sub gate electrodes 240 can be formed on one side and/or the other side of the gate electrode 140. For example, the first sub gate electrode 240 can be formed to protrude from one side of the gate electrode 140, for example, from the right side. More specifically, the first sub gate electrode 240 can include a 1-1 sub gate electrode 241 and a 1-2 sub gate electrode 243. The 1-1 sub gate electrode 241 and the 1-2 sub gate electrode 243 can be disposed on one side of the gate electrode 140, for example, on the right side. The 1-1 sub gate electrode 241 and the 1-2 sub gate electrode 243 can protrude from the gate electrode 140 and overlap with a portion of the active layer 120. For example, the 1-1 sub gate electrode 241 and the 1-2 sub gate electrode 243 can protrude from the gate electrode 140 and overlap with one side of the active layer 120, for example, a right-side region of the active layer 120 that does not overlap with the gate electrode 140.

In addition, the 1-1 sub gate electrode 241 can protrude and extend from the second portion 143 of the gate electrode 140, and the 1-2 sub gate electrode 243 can protrude and extend from the third portion 145 of the gate electrode 140. Also, the 1-1 sub gate electrode 241 and the 1-2 sub gate electrode 243 can extend in different directions with respect to the active layer 120 and overlap with a portion of the active layer 120. For example, the 1-1 sub gate electrode 241 can extend from one side of the active layer 120, for example, the upper side, and overlap with a portion of the active layer 120, and the 1-2 sub gate electrode 243 can extend from the other side of the active layer 120, for example, the lower side, and overlap with another portion of the active layer 120.

As further shown in FIG. 3, the 1-1 sub gate electrode 241 includes a 1-1 extension portion 241a extending in the first direction X from the second portion 143 of the gate electrode 140 and a 1-1 electrode portion 241b extending in the second direction Y from one end of the 1-1 extension portion 241a. The 1-1 extension portion 241a can extend from one side of the gate electrode 140, for example, the right side, so that the distance between the one side of the gate electrode 140 and the 1-1 electrode portion 241b becomes a first length L1. The 1-1 electrode portion 241b can also be disposed to extend from one side of the 1-1 extension portion 241a and cover a portion of the active layer 120. In more detail, the 1-1 electrode portion 241b can be disposed to overlap with a portion of one side of the active layer 120, for example, a portion of the right side, and the 1-1 electrode portion 241b can extend along the second direction Y while overlapping with the upper side of the active layer 120 and while not overlapping with the lower side of the active layer 120.

Accordingly, by being formed in this method, the 1-1 sub gate electrode 241 can be disposed to overlap with the upper side of the active layer 120 on a plane while being spaced apart from the lower side of the active layer 120 by a first distance d1. Accordingly, the 1-1 sub gate electrode 241 may not cross the active layer 120 in the second direction Y.

As still further shown in FIG. 3, the 1-2 sub gate electrode 243 includes a 1-2 extension portion 243a extending in the first direction X from the third portion 145 of the gate electrode 140 and a 1-2 electrode portion 243b extending in the second direction Y from one end of the 1-2 extension portion 243a. The 1-2 extension portion 243a can extend from one side of the gate electrode 140, for example, the right side, so that the distance between the one side of the gate electrode 140 and the 1-2 electrode portion 243b becomes a second length L2. Also, the second length L2 between the 1-2 electrode portion 243b of the 1-2 sub gate electrode 243 and the gate electrode 140 can be disposed differently from the first length L1 between the 1-1 electrode portion 241b of the 1-1 sub gate electrode 241 and the gate electrode 140. By forming in this method, the 1-1 sub gate electrode 241 and the 1-2 sub gate electrode 243 may not contact each other in an area overlapping the active layer 120 and may not be disposed on the same line.

In addition, the 1-2 electrode portion 243b can be disposed to extend from one side of the 1-2 extension portion 243a and cover another portion of the active layer 120. In more detail, the 1-2 electrode portion 243b can be disposed to overlap another portion of one side of the active layer 120, for example, the right side, and the 1-2 electrode portion 243b can extend along the second direction Y while overlapping the lower side of the active layer 120 and while not overlapping the upper side of the active layer 120.

Accordingly, by being formed in this method, the 1-2 sub gate electrode 243 can be provided to overlap with the lower side of the active layer 120 on a plane while being spaced apart from the upper side of the active layer 120 by a second distance D2. Accordingly, the 1-2 sub gate electrode 243 may not cross the active layer 120 in the second direction Y.

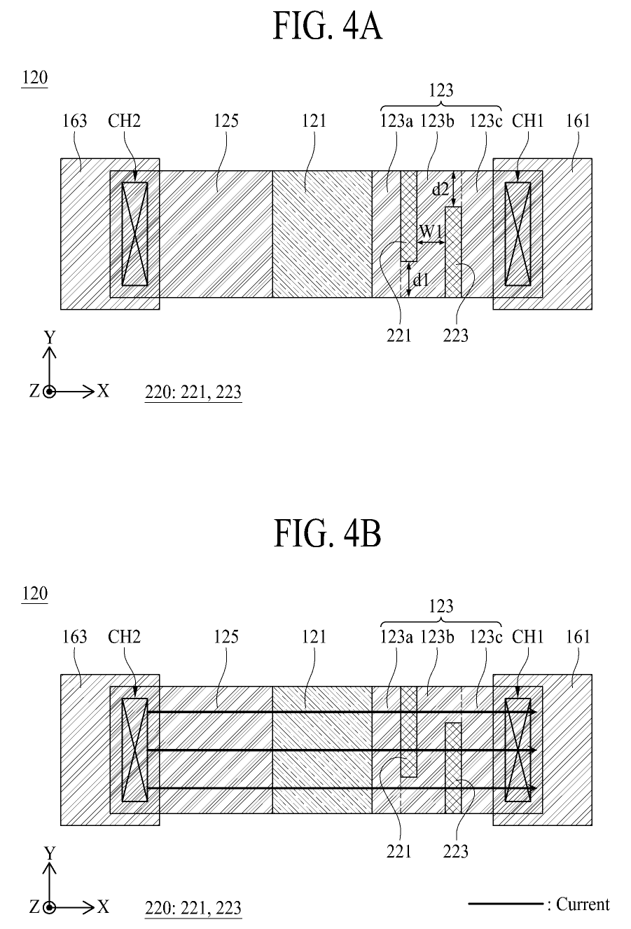

In addition, the 1-2 electrode portion 243b of the 1-2 sub gate electrode 243 and the 1-1 electrode portion 241b of the 1-1 sub gate electrode 241 can be disposed to face each other. For example, one side of the 1-1 electrode portion 241b, for example, the right side, can face one side of the 1-2 electrode portion 243b, for example, the left side. The 1-1 sub gate electrode 241 and the 1-2 sub gate electrode 243 are formed to be spaced apart from each other in an area overlapping the active layer 120. For example, the first-first electrode portion 241b of the 1-1 sub gate electrode 241 and the 1-2 electrode portion 243b of the 1-2 sub gate electrode 243 can be spaced apart from each other by a first width W1 in the first direction X. By forming in this method, the resistance of one area of the active layer 120, for example, the right area of the active layer 120 that is exposed without overlapping the gate electrode 140, can be relatively increased. This will be described in more detail with reference to FIG. 4A.

According to one embodiment of the present disclosure, the gate electrode 140, the 1-1 sub gate electrode 241, and the 1-2 sub gate electrode 243 can be formed integrally with each other. Accordingly, the gate electrode 140, the 1-1 sub gate electrode 241, and the 1-2 sub gate electrode 243 can receive the same voltage. The source electrode 161 can be disposed on one side of the active layer 120, for example, on the right side, and can be electrically connected to one side of the active layer 120 through the first contact hole CH1. In addition, the drain electrode 163 can be disposed on the other side of the active layer 120, for example, on the right side, and can be electrically connected to the other side of the active layer 120 through a second contact hole CH2.

Next, FIGS. 4A and 4B are schematic plan views of a thin film transistor substrate according to an embodiment of the present disclosure. FIG. 4A is a plan view schematically illustrating the configuration of an active layer, a source electrode, and a drain electrode of a thin film transistor substrate according to the embodiment of FIG. 3, and FIG. 4B is a plan view schematically illustrating a state in which current flows along the source electrode and the drain electrode when a voltage higher than a threshold voltage is applied to the gate electrode and the first sub gate electrode.

First, as can be seen in FIG. 4A, the active layer 120 includes a channel part 121, a first connection part 123, a second connection part 125, and a first sub channel part 220. The channel part 121 can be defined as a non-conductorized (i.e., not made conductive) region in the process of performing a conductive process using the gate electrode (see 140 in FIG. 3) as a mask. The channel part 121 can maintain semiconductor characteristic because it is not conductorized (i.e., made conductive). The “conductorized” process can be defined as a process of imparting conductivity to an oxide semiconductor material, and therefore an oxide semiconductor material that has undergone the conductorized process can be conductive. The conductorized process can include, for example, a doping process using dopant ions and a plasma process that conducts by applying plasma.

As can also be seen in FIG. 4A, the first connection part 123 can be disposed on one side of the channel part 121, for example, on the right side, and the second connection part 125 can be disposed on the other side of the channel part 121, for example, on the left side. The first connection part 123 and the second connection part 125 correspond to portions that are exposed to the outside and not covered by the gate electrode or the sub gate electrode (see 140 and 240 in FIG. 3) during the conductorized process. Therefore, the first connection part 123 and the second connection part 125 can have a conductive property due to the conductorized process. In this situation, the first connection part 123 and the second connection part 125 have relatively high electrical conductivity compared to the channel part 121, and the first connection part 123 and the second connection part 125 can be used as wiring or electrodes due to the high electrical conductivity characteristic.

According to one embodiment of the present disclosure, one of the regions of the first connection part 123 and the second connection part 125 can be formed by the first sub gate electrode (see 240 in FIG. 3) to include a first region 123a, a second region 123b, and a third region 123c. Further, the first region 123a can be disposed on one side of the channel part 121, for example, on the right side, and the third region 123c can be disposed on one side of the active layer 120, for example, on the right end, and can be electrically connected to the source electrode 161 through the first contact hole CH1.

Further, the second region 123b can be disposed between the first region 123a and the third region 123c and can be a region that controls the resistance of the first connection part 123. In more detail, the second region 123b of the first connection part 123 is formed between the 1-1 sub channel part 221 and the 1-2 sub channel part 223, thereby controlling the length, width, and/or spacing between the 1-1 sub channel part 221 and the 1-2 sub channel part 223 to appropriately control the electrical resistance of the second region 123b.

According to one embodiment of the present disclosure, at least two sub channel parts 220 can be formed in an area overlapping the 1-1 sub gate electrode (see 241 in FIG. 3) and the 1-2 sub gate electrode (see 243 in FIG. 3). The sub channel part 220 includes the 1-1 sub channel part 221 formed using the 1-1 sub gate electrode (see 241 in FIG. 3) as a mask, and the 1-2 sub channel part 223 formed using the 1-2 sub gate electrode (see 243 in FIG. 3) as a mask.

Also, the 1-1 sub channel part 221 and the 1-2 sub channel part 223 overlap with the 1-1 sub gate electrode (see 241 in FIG. 3) and the 1-2 sub gate electrode (see 243 in FIG. 3), respectively, and thus can be a region that maintains semiconductor characteristic without being conductive. The 1-1 sub channel part 221 can also extend from one side of the active layer 120, for example, the upper side, along the second direction Y, and the 1-2 sub channel part 223 can extend from the other side of the active layer 120, for example, the lower side, along the second direction Y. Still further, the 1-1 sub channel part 221 and the 1-2 sub channel part 223 can be disposed to face each other. For example, one side of the 1-1 sub channel part 221, for example, the right side, can face one side of the 1-2 sub channel part 223, for example, the left side. Also, a portion of the first connection part 123 can be disposed between the 1-1 sub channel part 221 and the 1-2 sub channel part 223.

In addition, the 1-1 sub channel part 221 can constitute a portion of one side of the active layer 120, for example, an upper side, and can be formed to be spaced apart from the other side of the active layer 120, for example, a lower side, by a first distance d1. Further, the 1-2 sub channel part 223 can constitute a portion of the other side of the active layer 120, for example, a lower side, and can be formed to be spaced apart from one side of the active layer 120, for example, an upper side, by a second distance d2. The 1-1 sub channel part 221 and the 1-2 sub channel part 223 can therefore be formed to be spaced apart from each other by the first width w1. In this situation, the first width W1 can mean the shortest distance between one side of the 1-1 sub channel part 221, for example, the right side, and one side of the 1-2 sub channel part 223, for example, the left side.

According to one embodiment of the present disclosure, by adjusting the first distance d1, the second distance d2, and the first width W1, the resistance of the second region 123b of the first connection part 123 can be appropriately adjusted. Accordingly, the resistance of the first connection part 123 can be relatively increased by the 1-1 sub channel part 221 and the 1-2 sub channel part 223.

In addition, by relatively increasing the resistance of the first connection part 123, when the thin film transistor substrate according to one embodiment of the present disclosure is in a non-driven (turn-off) state, the voltage distributed to the channel part 121 by the voltage applied to each of the source electrode 161 and the drain electrode 163 can be relatively lowered. In this situation, since the voltage distributed to the channel part 121 is relatively low, even when the thin film transistor substrate is in a non-driven (turn-off) state, the phenomenon of electrons being trapped inside the active layer 120 by the voltage distributed to the channel part 121, the so-called electron trap, can be eliminated or minimized. Accordingly, the phenomenon of the threshold voltage (Vth) shifting in the positive (+) direction can be prevented.

Next, as can be seen in FIG. 4B, when the thin film transistor substrate according to one embodiment of the present disclosure is turned on, current can flow across the 1-1 sub channel part 221 and the 1-2 sub channel part 223. According to one embodiment of the present disclosure, the gate electrode (see 140 in FIG. 3) and the first sub gate electrode (see 240 in FIG. 3) can receive the same voltage. Therefore, when a voltage higher than the threshold voltage (Vth) is applied to the gate electrode (see 140 in FIG. 3) and the first sub gate electrode (see 240 in FIG. 3), the channel part 121, the 1-1 sub channel part 221, and the 1-2 sub channel part 223 can be in a state in which charge carriers can flow due to an electric field formed by the gate electrode (see 140 in FIG. 3) and the first sub gate electrode see 240 in FIG. 3, respectively. Thus, current can move sequentially through the drain electrode 163, the second connection part 125, the channel part 121, the first connection part 123, the 1-1 sub channel part 221 and/or the 1-2 sub channel part 223 and the source electrode 161. Accordingly, a thin film transistor whose on-current characteristic are not deteriorated by the 1-1 sub channel part 221 and the 1-2 sub channel part 223 can be implemented.

According to one embodiment of the present disclosure, when the thin film transistor substrate is in a non-driven state, by increasing the resistance of the first connection part 123 and/or the second connection part 125, the voltage applied between one end and the other end of the channel part 121 by the source electrode 161 and the drain electrode 163 is lowered, thereby preventing electrons from being trapped and the threshold voltage (Vth) from moving in the positive (+) direction. Meanwhile, when the thin film transistor substrate is in a driven state, the current can flow across the channel part 121, the 1-1 sub channel part 221, and the 1-2 sub channel part 223 without bypassing the 1-1 sub channel part 221 and the 1-2 sub channel part 223 by the electric field in the third direction Z formed by the gate electrode 140, the 1-1 sub gate electrode 241, and the 1-2 sub gate electrode 243 in the channel part 121, the 1-1 sub channel part 221, and the 1-2 sub channel part 223. Therefore, in a non-driven state, a device having improved reliability can be implemented by preventing a high voltage from being applied to the channel part 121, and in a driven state, a device in which the on-current characteristic is not deteriorated can be implemented.

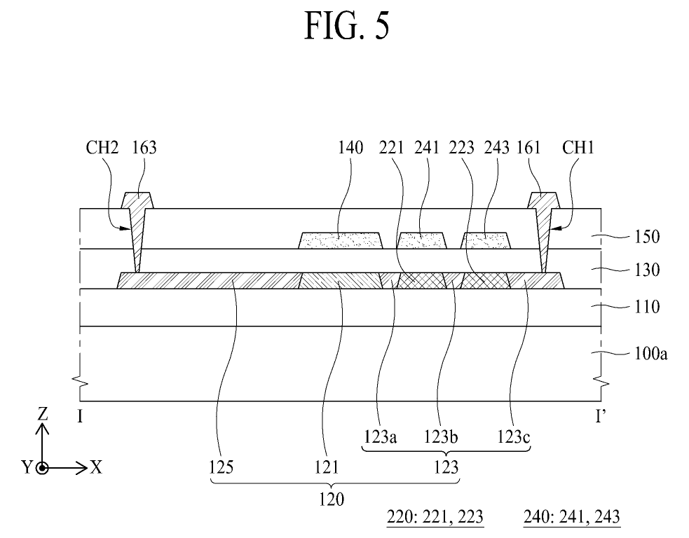

FIG. 5 is a cross-sectional view of a thin film transistor substrate according to one embodiment of the present disclosure. More specifically, , FIG. 5 relates to cross-section I-I' of FIG. 3. As can be seen in FIG. 5, a thin film transistor substrate according to one embodiment of the present disclosure includes a first substrate 100a, a buffer layer 110, an active layer 120, a gate insulating layer 130, a gate electrode 140, a first sub gate electrode 240, an interlayer insulating layer 150, a source electrode 161, and a drain electrode 163.

The first substrate 100a can be made of glass or plastic. In particular, the first substrate 100a can be made of a transparent plastic having flexible property, for example, polyimide. When polyimide is used as the first substrate 100a, considering that a high temperature deposition process is performed on the first substrate 100a, a heat resistant polyimide that can withstand high temperatures can be used.

Also, the buffer layer 110 is formed on the first substrate 100a, and can protect the active layer 120 by blocking air and moisture. The buffer layer 110 can be formed of an inorganic insulating material such as silicon oxide, silicon nitride, or metal oxide, but is not necessarily limited thereto and can be formed of an organic insulating material. The buffer layer 110 can also be formed of a single layer or can be formed of multiple layers.

In addition, the active layer 120 can be disposed on the buffer layer 110. The exemplary active layer 120 is composed of a channel part 121, a first connection part 123, a second connection part 125, a 1-1 sub channel part 221, and a 1-2 sub channel part 223.

Further, the channel part 121, the 1-1 sub channel part 221, and the 1-2 sub channel part 223 can be regions that are not made conductive in the conductorized process by using the gate electrode 140, the 1-1 sub gate electrode 241, and the 1-2 sub gate electrode 243 as masks, respectively. Accordingly, the channel part 121, the 1-1 sub channel part 221, and the 1-2 sub channel part 223 can maintain a semiconductor characteristic. The 1-1 sub channel part 221 and the 1-2 sub channel part 223 can be disposed on one side of the channel part 121, for example, on the right side, and can be disposed between one end of the channel part 121, for example, the right end, and one end of the active layer 120, for example, the right end. According to one embodiment of the present disclosure, in a non-driven (turn-off) state of the thin film transistor substrate, the resistance of the first connection part 123 can be relatively increased by the 1-1 sub channel part 221 and the 1-2 sub channel part 223. According to one embodiment of the present disclosure, when a voltage higher than a threshold voltage (Vth) is applied to the gate electrode 140, the 1-1 sub gate electrode 241, and the 1-2 sub gate electrode 243, charges are accumulated on the surfaces of the channel part 121, the 1-1 sub channel part 221, and the 1-2 sub channel part 223, and thus current can flow.

As is further shown in FIG. 5, the first connection part 123 can be disposed on one side of the channel part 121, for example, on the right side, and the second connection part 125 can be disposed on the other side of the channel part 121, for example, on the left side. The first connection part 123 and the second connection part 125 can be provided with a conductive property by a conductorized process that performs ion doping or plasma treatment on a semiconductor material using the gate electrode 140, the 1-1 sub gate electrode 241, and the 1-2 sub gate electrode 243 as masks.

Through the conductorized process, a portion of the active layer 120 can be conductorized and have a conductive property. In this situation, the first connection part 123 and the second connection part 125 can be conductorized and be conductive through the conductorized process, and the first connection part 123 and the second connection part 125 can have superior conductivity compared to the channel part 121, the 1-1 sub channel part 221, or the 1-2 sub channel part 223. Thus, the first connection part 123 and the second connection part 125 can also function as a wiring or a source/drain electrode.

As is further shown in FIG. 5, the first connection part 123 comprises a first region 123a, a second region 123b, and a third portion 123c. The first portion 123a can be disposed between the channel part 121 and the 1-1 sub channel part 221, the second region 123b can be disposed between the 1-1 sub channel part 221 and the 1-2 sub channel part 223, and the third portion 123c can be disposed on one side, for example, the right side, of the 1-2 sub channel part 223. According to one embodiment of the present disclosure, the second region 123b can be disposed between the 1-1 sub channel part 221 and the 1-2 sub channel part 223 to function as a resistance adjustment region of the first connection part 123. Because the description related thereto is the same as that described in FIG. 4A, repeated content will be omitted.

On addition, the active layer 120 of FIG. 5 can be formed by including a semiconductor material, for example, an oxide semiconductor material. The oxide semiconductor material can include, for example, at least one of an IZO InZnO based oxide semiconductor material, an IGO InGaO based oxide semiconductor material, an ITO InSnO based oxide semiconductor material, an IGZO InGaZnO based oxide semiconductor material, an IGZTO InGaZnSnO based oxide semiconductor material, a GZTO GaZnSnO based oxide semiconductor material, a GZO GaZnO based oxide semiconductor material, an ITZO InSnZnO based oxide semiconductor material, and an FIZO FeInZnO based oxide semiconductor material.

Also, the gate insulating layer 130 can be disposed on the active layer 120. In detail, the gate insulating layer 130 can be disposed on the entire surface of the first substrate 100a and can be disposed on the active layer 120 and the buffer layer 110. As a result, the active layer 120 can be disposed in a form in which it is surrounded by the buffer layer 110 and the gate insulating layer 130. The gate insulating layer 130 can include, but is not limited to, a silicon nitride film (SiNx) or a silicon oxide film (SiOx). The gate insulating layer 130 can be formed of a single layer or multiple layers including an inorganic insulator and/or an organic insulator. Meanwhile, although not illustrated, the gate insulating layer 130 is not limited to being disposed on the entire surface of the first substrate 100a, and can be pattern-formed to match one end and the other end of the gate electrode 140.

The gate electrode 140 can also be disposed on the gate insulating layer 130. The gate electrode 140 can be disposed on the active layer 120. The gate electrode 140 can, for example, overlap with the channel part 121 of the active layer 120. The gate electrode 140 can include at least one of an aluminum based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The gate electrode 140 can have a structure including a single metal layer or a multi-layer including at least two metal layers each having different physical properties.

Also, the 1-1 sub gate electrode 241 and the 1-2 sub gate electrode 243 can be formed on the gate insulating layer 130, and the 1-1 sub gate electrode 241 and the 1-2 sub gate electrode 243 can be formed on the same layer as the gate electrode 140. The 1-1 sub gate electrode 241 can overlap with the 1-1 sub channel part 221, and the 1-2 sub gate electrode 243 can overlap with the 1-2 sub channel part 223. The 1-1 sub gate electrode 241 and the 1-2 sub gate electrode 243 can be formed of the same material as the gate electrode 140. For example, the 1-1 sub gate electrode 241 and the 1-2 sub gate electrode 243 can include at least one of an aluminum based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The gate electrode 140 can also have a structure including a single metal layer or a multi-layer including at least two metal layers each having different physical properties. Accordingly, the gate electrode 140, the 1-1 sub gate electrode 241, and the 1-2 sub gate electrode 243 can receive the same voltage. Therefore, by the voltage applied to the gate electrode 140, the 1-1 sub gate electrode 241, and the 1-2 sub gate electrode 243, charges can move to the channel part 121, the 1-1 sub channel part 221, and the 1-2 sub channel part 223, which in turn cause current to flow.

Further, the interlayer insulating layer 150 insulates between the gate electrode 140 and the source electrode 161, and further insulates between the gate electrode 140 and the drain electrode 163. The interlayer insulating layer 150 can be formed of a single layer or a plurality of layers including an inorganic insulator and/or an organic insulator. Furthermore, the interlayer insulating layer 150 insulates between the 1-1 sub gate electrode 241 and the 1-2 sub gate electrode 243 and the source electrode 161, and further insulates between the 1-1 sub gate electrode 241 and the 1-2 sub gate electrode 243 and the drain electrode 163. The interlayer insulating layer 150 can be provided with a first contact hole CH1 and a second contact hole CH2. Accordingly, a portion of one upper surface of the active layer 120 can be exposed through the first contact hole CH1, and further, a portion of the other upper surface of the active layer 120 can be exposed through the second contact hole CH2. In detail, a portion of the upper surface of the first connection part 123 can be exposed through the first contact hole CH1, and a portion of the upper surface of the second connection part 125 can be exposed through the second contact hole CH2.

In addition, the source electrode 161 and the drain electrode 163 can be disposed on the interlayer insulating layer 150. The source electrode 161 and the drain electrode 163 can be formed of the same material as the gate electrode 140, but are not limited thereto and can be formed of a material according to knowledge in the art, and the source electrode 161 and the drain electrode 162 can be formed on the same layer as the gate electrode 140.

Still further, in related embodiments, a conductive light shield can be disposed under the active layer 120 to act as a second (lower) gate electrode. This second gate electrode can, for example, overlap with the gate electrode 140, the 1-1 sub gate electrode 241, and the 1-2 sub gate electrode 243. As with the gate electrode 140, the second gate electrode can include at least one of an aluminum based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The second gate electrode can also have a structure including a single metal layer or a multi-layer including at least two metal layers each having different physical properties. The second / lower gate electrode can be electrically connected to the gate electrode 140, the 1-1 sub gate electrode 241, and the 1-2 sub gate electrode 243, or in other embodiments can be connected to a constant or programmable voltage. Accordingly, the off resistance of the active layer 120 can be increased.

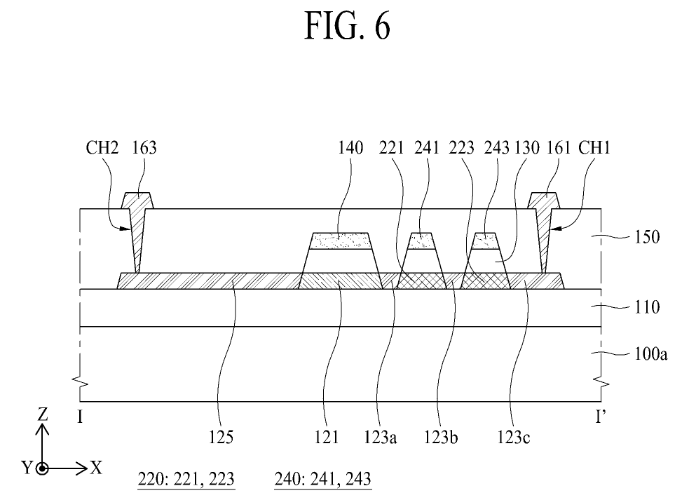

FIG. 6 is a cross-sectional view of a thin film transistor substrate according to another embodiment of the present disclosure. In this embodiment, FIG. 6 relates to cross-section I-I' of FIG. 3. Because the embodiment of FIG. 6 is identical to the embodiment of FIG. 5 except for the configuration of the gate insulating film, the following description will focus on the different configuration. As can be seen in FIG. 6, a thin film transistor substrate according to another embodiment of the present disclosure comprises a first substrate 100a, a buffer layer 110, an active layer 120, a gate insulating layer 130, a gate electrode 140, an interlayer insulating layer 150, a source electrode 161, and a drain electrode 163.

In the embodiment of FIG. 6, unlike in FIG. 5, the gate insulating layer 130 can be disposed to correspond to the gate electrode 140, the 1-1 sub gate electrode 241, and the 1-2 sub gate electrode 243. In detail, one end and the other end of a portion of the gate insulating layer 130 can be disposed to correspond to one end and the other end of the gate electrode 140, one end and the other end of another portion of the gate insulating layer 130 can be disposed to correspond to one end and the other end of the 1-1 sub gate electrode 241, and another portion of the gate insulating layer 130 can be disposed to correspond to one end and the other end of the 1-2 sub gate electrode 243.

In this embodiment, a portion of the gate insulating layer 130 corresponding to the gate electrode 140 can be disposed to be in contact with the upper surface of the channel part 121, another portion of the gate insulating layer 130 corresponding to the 1-1 sub gate electrode 241 can be disposed to be in contact with the upper surface of the 1-1 sub channel part 221, and yet another portion of the gate insulating layer 130 corresponding to the 1-2 sub gate electrode 243 can be disposed to be in contact with the upper surface of the 1-2 sub channel part 223. Since the gate insulating layer 130 is disposed to correspond to each of the gate electrode 140, the 1-1 sub gate electrode 241, and the 1-2 sub gate electrode 243, the interlayer insulating layer 150 can be disposed to be in contact with the upper surfaces of the first connection part 123 and the second connection part 125 where the gate insulating layer 130 is not formed.

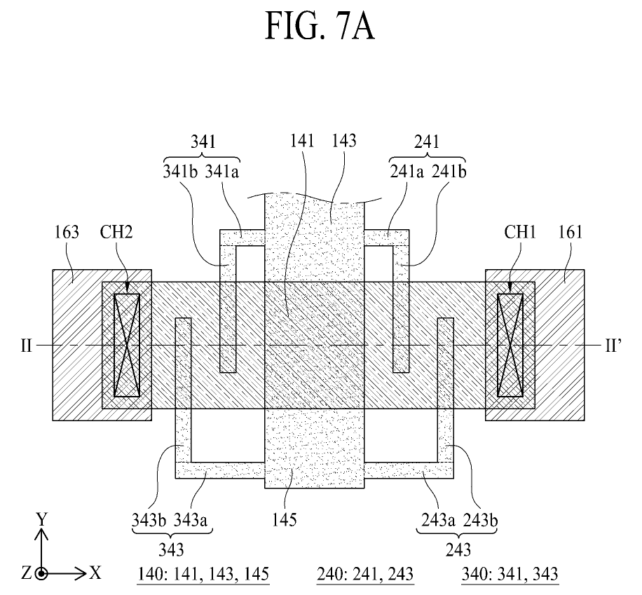

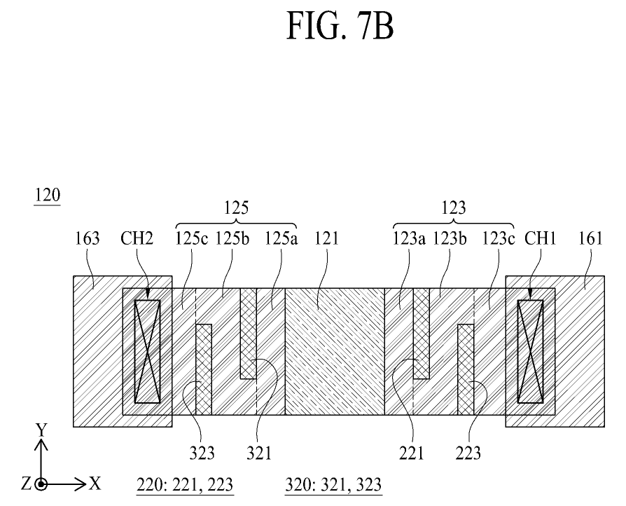

FIG. 7A is a plan view of a thin film transistor substrate according to another embodiment of the present disclosure. Because the embodiment of FIG. 7A is identical to the embodiment of FIG. 3 except for the configuration of the sub gate electrode, the following description will focus on the different configuration. As can be seen in FIG. 7A, a thin film transistor substrate according to another embodiment of the present disclosure comprises an active layer 120 (see FIG. 7B), a gate electrode 140, a first sub gate electrode 240, a second sub gate electrode 340, a source electrode 161, and a drain electrode 163.

In addition, at least two first sub gate electrodes 240 can be disposed on one side of the gate electrode 140, for example, on the right side, and at least two second sub gate electrodes 340 can be disposed on the other side of the gate electrode 140, for example, on the left side. The first sub gate electrode 240 is formed by including the 1-1 sub gate electrode 241 and the 1-2 sub gate electrode 243 which are formed by protruding from one side of the gate electrode 140, and the second sub gate electrode 340 is formed by including the 2-1 sub gate electrode 341 and the 2-2 sub gate electrode 343 which are formed by protruding from the other side of the gate electrode 340.

Further, the 2-1 sub gate electrode 341 and the 2-2 sub gate electrode 343 can protrude from the gate electrode 140 and overlap with a portion of the active layer 120. For example, the 2-1 sub gate electrode 341 and the 2-2 sub gate electrode 343 can protrude from the gate electrode 140 and overlap with the other side of the active layer 120, for example, the left side of the active layer 120 that does not overlap with the gate electrode 140. Also, the 2-1 sub gate electrode 341 can also protrude and extend from the second portion 143 of the gate electrode 140, and the 2-2 sub gate electrode 343 can protrude and extend from the third portion 145 of the gate electrode 140. Further, the 2-1 sub gate electrode 341 and the 2-2 sub gate electrode 343 can extend in different directions with respect to the active layer 120 and overlap with a portion of the active layer 120. For example, the 2-1 sub gate electrode 341 can extend from one side of the active layer 120, for example, the upper side, and overlap with a portion of the active layer 120, and the 2-2 sub gate electrode 343 can extend from the other side of the active layer 120, for example, the lower side, and overlap with another portion of the active layer 120.

In addition, the 2-1 sub gate electrode 341 includes a 2-1 extension portion 341a extending in the first direction X from the second portion 143 of the gate electrode 140 and a 2-1 electrode portion 341b extending in the second direction Y from one end of the 2-1 extension portion 341a. Also, the 2-1 extension portion 341a can be disposed so that it extends from the other side of the gate electrode 140, for example, the left side, so that the distance between the other side of the gate electrode 140 and the 2-1 electrode portion 341b is spaced apart by a constant length. Further, the 2-1 electrode portion 341b can be disposed to extend from one side of the 2-1 extension portion 341a and cover a portion of the active layer 120. In detail, the 2-1 electrode portion 341b can be disposed to overlap with a portion of the other side of the active layer 120, for example, a left side, and the 2-1 electrode portion 341b can extend along the fourth direction Y while overlapping with the upper side of the active layer 120 and while not overlapping with the lower side of the active layer 120.

By being formed in this method, the 2-1 sub gate electrode 341 can be disposed to overlap with the upper side of the active layer 120 on a plane while being spaced apart from the lower side of the active layer 120 by a certain distance. Accordingly, the 2-1 sub gate electrode 341 does not cross the active layer 120 in the second direction Y.

As is also shown in FIG. 7A, the 2-2 sub gate electrode 343 includes a 2-2 extension portion 343a extending in the first direction X from the third portion 145 of the gate electrode 140 and a 2-2 electrode portion 343b extending in the second direction Y from one end of the 2-2 extension portion 343a. The 2-2 extension portion 343a can be provided so that it extends from the other side of the gate electrode 140, for example, the left side, so that the distance between the other side of the gate electrode 140 and the 2-2 electrode portion 343b is spaced apart by a constant length. In addition, the length between the 2-2 electrode portion 343b of the 2-2 sub gate electrode 343 and the gate electrode 140 can be disposed differently from the length between the 2-1 electrode portion 341b of the 2-1 sub gate electrode 341 and the gate electrode 140. By forming in this method, the 2-1 sub gate electrode 341 and the 2-2 sub gate electrode 343 may not contact each other in the area overlapping the active layer 120 and may not be disposed on the same line.

In addition, the 2-2 electrode portion 343b can be disposed to extend from one side of the 2-2 extension portion 343a and cover another portion of the active layer 120. In more detail, the 2-2 electrode portion 343b can be disposed to overlap another portion of the other side of the active layer 120, for example, the left side, and the 2-2 electrode portion 343b can extend along the second direction Y while overlapping the lower side of the active layer 120 and not overlapping the upper side of the active layer 120. By being formed in this method, the 2-2 sub gate electrode 343 can be disposed to overlap with the lower side of the active layer 120 on a plane while being spaced apart from the upper side of the active layer 120 by a fourth distance D2. Accordingly, the 2-2 sub gate electrode 343 may not cross the active layer 120 in the second direction Y.

Still further, the 2-2 electrode portion 343b of the 2-2 sub gate electrode 343 and the 2-1 electrode portion 341b of the 2-1 sub gate electrode 341 can be disposed to face each other. For example, one side of the 2-1 electrode portion 341b, for example, the left side, can face one side of the 2-2 electrode portion 343b, for example, the right side.

Also, the 2-1 sub gate electrode 341 and the 2-2 sub gate electrode 343 are formed to be spaced apart from each other in an area overlapping the active layer 120. For example, the 2-1 electrode portion 341b of the 2-1 sub gate electrode 341 and the 2-2 electrode portion 343b of the 2-2 sub gate electrode 343 can be spaced apart from each other by a certain width in the first direction X. By forming in this method, the resistance of the other area of the active layer 120, for example, the right area of the active layer 120 that is exposed without overlapping with the gate electrode 140, can be relatively increased.

According to another embodiment of the present disclosure, the gate electrode 140, the 1-1 sub gate electrode 241, and the 1-2 sub gate electrode 243 can be formed integrally with each other. Accordingly, the gate electrode 140, the 1-1 sub gate electrode 241, the 1-2 sub gate electrode 243, the 2-1 sub gate electrode 341, and the 2-2 sub gate electrode 343 can receive the same voltage.

According to still another embodiment of the present disclosure, the resistance of the second connection portion (see 125 of FIG. 4A) can be relatively increased by the 2-1 sub gate electrode 341 and the 2-2 sub gate electrode 343. Since this is the same as the description in FIG. 4A, a repeated description will be omitted. However, since the resistance of the second connection portion (see 125 of FIG. 4A) is relatively increased by the 2-1 sub gate electrode 341 and the 2-2 sub gate electrode 343, the voltage applied to one end and the other end of the channel part (see 121 of FIG. 4A) becomes relatively lower, so that the degree to which charges, for example, electrons, are trapped can be further reduced, and accordingly, the threshold voltage (Vth) can be prevented from shifting in the positive (+) direction (Positive Shift).

FIG. 7B is a schematic plan view of a thin film transistor substrate that briefly illustrates how a channel part, a first sub channel part, and a second sub channel part are formed in FIG. 7A. As can be seen in FIG. 7B, the active layer 120 includes a channel part 121, a first connection part 123, a second connection part 125, a first sub channel part 220, and a second sub channel part 320.

According to one embodiment of the present disclosure, any one region of the second connection part 125 can be formed by the second sub gate electrode (see 340 of FIG. 7A) to include a first region 125a, a second region 125b, and a third region 125c. The first region 125a can be disposed on the other side of the channel part 121, for example, on the left side, and the third region 125c can be disposed on the other end of the active layer 120, for example, on the left end, and can be electrically connected to the drain electrode 161 through the second contact hole CH2. The second region 125b can be disposed between the first region 125a and the third region 125c. The second region 125b can be a region that controls the resistance of the second connection part 125. In more detail, the second region 125b of the second connection part 125 is formed between the 2-1 sub channel part 221 and the 2-2 sub channel part 323, thereby controlling the length, width, and/or spacing between the 2-1 sub channel part 321 and the 2-2 sub channel part 323 to appropriately control the electrical resistance of the second region 125b.

In addition, at least two sub-channel parts 320 can be formed in an area overlapping the 2-1 sub gate electrode (see 341 of FIG. 7A) and the 2-2 sub gate electrode (see 343 of FIG. 7A). The sub channel part 320 includes the 2-1 sub channel part 321 formed using the 2-1 sub gate electrode (see 341 of FIG. 7A) as a mask, and the 2-2 sub channel part 323 formed using the 2-2 sub gate electrode (see 343 of FIG. 7A) as a mask. Since the 2-1 sub channel part 321 and the 2-2 sub channel part 323 overlap with the 2-1 sub gate electrode (see 341 of FIG. 7A) and the 2-2 sub gate electrode (see 343 of FIG. 7A), respectively, the 2-1 sub channel part 321 and the 2-2 sub channel part 323 can be regions that maintain semiconductor characteristic without being imparted with a conductive characteristic in the conductorized process. Further, the 2-1 sub channel part 321 can extend from one side of the active layer 120, for example, the upper side, along the second direction Y, and the 2-2 sub channel part 323 can extend from the other side of the active layer 120, for example, the lower side, along the second direction Y.

As is further shown in FIG. 7B, the 2-1 sub channel part 321 and the 2-2 sub channel part 323 can be disposed to face each other. For example, one side of the 2-1 sub channel part 321, for example, the left side, can face one side of the 2-2 sub channel part 323, for example, the right side. A portion of the second connection part 125 can also be disposed between the 2-1 sub channel part 321 and the 2-2 sub channel part 323. The 2-1 sub channel part 321 can constitute a part of one side of the active layer 120, for example, the upper side, and can be formed to be spaced apart from the other side of the active layer 120, for example, the lower side, by a certain distance. Similarly, the 2-2 sub channel part 323 can constitute a part of the other side of the active layer 120, for example, the lower side, and can be formed to be spaced apart from one side of the active layer 120, for example, the upper side, by a certain distance. Therefore, the 2-1 sub channel section 321 and the 2-2 sub channel section 323 can be formed spaced apart from each other by the predetermined width.

Further, the resistance of the second region 125b of the second connection part 125 can be appropriately adjusted by adjusting the width or length between the 2-1 sub channel part 321 and/or the 2-2 sub channel part 323. For example, the resistance of the second connection part 125 can be relatively increased by the 2-1 sub channel part 321 and the 2-2 sub channel part 323. Thus, by relatively increasing the resistance of the second connection part 125, when the thin film transistor substrate according to one embodiment of the present disclosure is in a non-driven (turn-off) state, the voltage distributed to the channel part 121 by the voltage applied to each of the source electrode 161 and the drain electrode 163 can be relatively lowered. In this embodiment, since the voltage distributed to the channel part 121 is relatively low, even when the thin film transistor substrate is in a non-driven (turn-off) state, the phenomenon of electrons being trapped inside the active layer 120 by the voltage distributed to the channel part 121, the so-called electron trap, can be eliminated or minimized. Accordingly, the phenomenon of the threshold voltage (Vth) shifting in the positive (+) direction can be prevented.

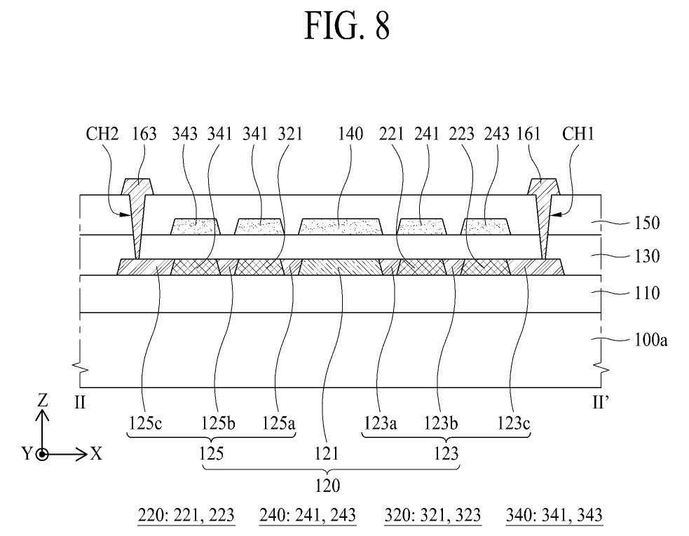

FIG. 8 is a cross-sectional view of a thin film transistor substrate according to another embodiment of the present disclosure. In this situation, FIG. 8 is taken along section II-II' of FIG. 7A. Meanwhile, the embodiment of FIG. 8 is identical to the embodiment of FIG. 5 except for the third sub gate electrode and the fourth sub gate electrode, and therefore, the following description will focus on the different configurations. As can be seen in FIG. 8, a thin film transistor substrate according to another embodiment of the present disclosure comprises a first substrate 100a, a buffer layer 110, an active layer 120, a gate insulating layer 130, a gate electrode 140, a first sub gate electrode 240, a second sub gate electrode 340, an interlayer insulating layer 150, a source electrode 161, and a drain electrode 163.

Further, the active layer 120 comprises a channel part, a first connection part 123, a second connection part 125, a 1-1 sub channel part 221, a 1-2 sub channel part 223, a 2-1 sub channel part 321, and a 2-2 sub channel part 323. The channel part 121, the 1-1 sub channel part 221, the 1-2 sub channel part 223, the 2-1 sub channel part 321, and the 2-2 sub channel part 323 can be regions that are not conductorized in the conductorized process by using the gate electrode 140, the 1-1 sub gate electrode 241, the 1-2 sub gate electrode 243, the 2-1 sub gate electrode 341, and the 2-2 sub gate electrode 343 as masks, respectively. Accordingly, the channel part 121, the 1-1 sub channel part 221, the 1-2 sub channel part 223, the 2-1 sub channel part 321, and the 2-2 sub channel part 323 can maintain semiconductor characteristic.

In addition, the 2-1 sub channel part 321 and the 2-2 sub channel part 323 can be disposed on the other side of the channel part 121, for example, on the left side, and can be disposed between the other end of the channel part 121, for example, the left end, and the other end of the active layer 120, for example, the left end. According to another embodiment of the present disclosure, in a non-driven (turn-off) state of the thin film transistor substrate, the resistance of the second connection part 125 can be relatively increased by the 2-1 sub channel part 321 and the 2-2 sub channel part 323. Thus, when a voltage higher than a threshold voltage (Vth) is applied to the gate electrode 140, the 1-1 sub gate electrode 241, the 1-2 sub gate electrode 243, the sub-3 gate electrode 341, and the 2-2 sub gate electrode 343, charges can be accumulated on the surfaces of the channel part 121, the 1-1 sub channel part 221, the 1-2 sub channel part 223, the 2-1 sub channel part 321, and the 2-2 sub channel part 323, causing current to flow. The first connection part 123 and the second connection part 125 can be provided with a conductive property by a conductorized process that performs ion doping or plasma treatment on a semiconductor material using the gate electrode 140, the 1-1 sub gate electrode 241, the 1-2 sub gate electrode 243, the 2-1 sub gate electrode 341, and the 2-2 sub gate electrode 343 as masks. Through the conductorized process, the first connection part 123 and the second connection part 125 have superior conductivity compared to the channel part 121, the 1-1 sub channel part 221, the 1-2 sub channel part 223, the 2-1 sub channel part 321 or the 2-2 sub channel part 323, and each of the first connection part 123 and the second connection part 125 can also function as a wiring or source/drain electrode.

Also, the second connection part 125 comprises a first portion 125a, a second portion 125b, and a third portion 125c. The first portion 125a can be disposed between the channel part 121 and the 2-1 sub channel part 321, the second portion 125b can be disposed between the 2-1 sub channel part 321 and the 2-2 sub channel part 323, and the third portion 125c can be disposed on one side, for example, the left side, of the 2-2 sub channel part 323. According to one embodiment of the present disclosure, the second portion 125b is disposed between the 2-1 sub channel part 321 and the 2-2 sub channel part 323 and can function as a resistance adjustment region of the second connection part 125. Meanwhile, the description related thereto is the same as that described in FIG. 7B, so repeated content will be omitted.

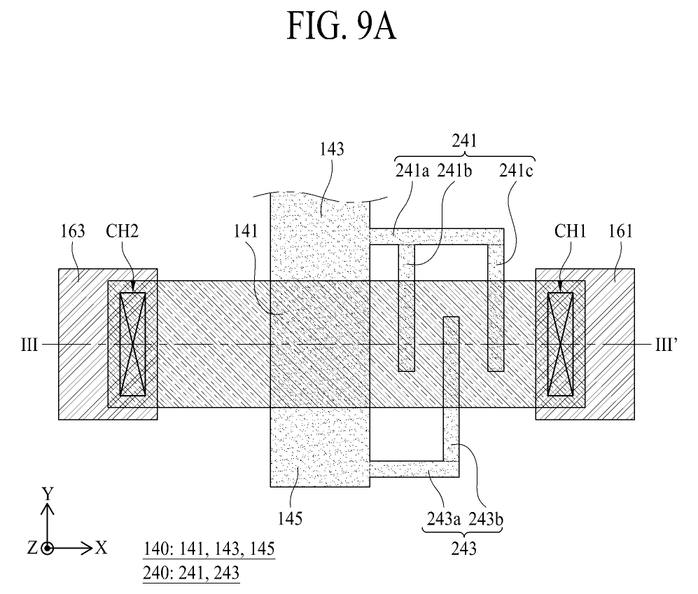

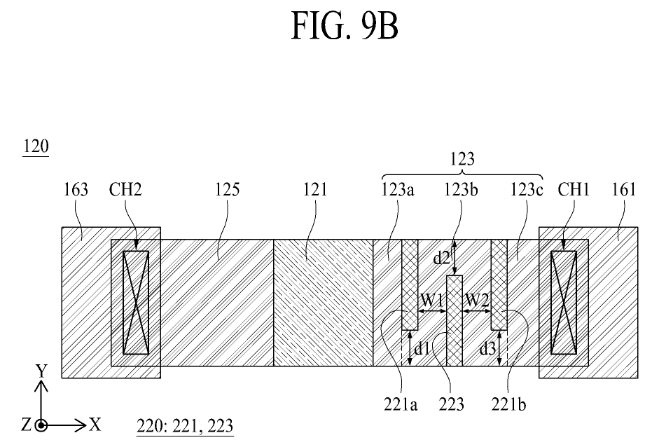

FIG. 9A is a plan view of a thin film transistor substrate according to another embodiment of the present disclosure. Because the embodiment of FIG. 9A is identical to the embodiment of FIG. 3 except for the configuration of the first sub gate electrode, the following description will focus on the different configuration. As can be seen in FIG. 9A, a thin film transistor substrate according to another embodiment of the present disclosure comprises an active layer 120 (see FIG. 9B), a gate electrode 140, a first sub gate electrode 240, a source electrode 161, and a drain electrode 163.

In addition, the first sub gate electrode 240 includes a 1-1 sub gate electrode 241 that protrudes and extends from the second portion 143 of the gate electrode 140 and a 1-2 sub gate electrode 243 that protrudes and extends from the third portion 145 of the gate electrode 140. According to another embodiment of the present disclosure, the 1-1 sub gate electrode 241 includes a 1-1 extension portion 241a extending from one side of the gate electrode 140, a 1-1a electrode portion 241b extending and protruding from one side of the 1-1 extension portion 241a, and a 1-1b electrode portion 241c. The 1-1a electrode portion 241b, the 1-2 electrode portion 243b, and the 1-1b electrode portion 241c can be alternately arranged along the second direction X. By forming in this method, the resistance of the active layer 120 can be relatively increased. This will be described in more detail with reference to FIG. 9B. The only point that two electrode parts are formed on the 1-1 sub gate electrode 241 and one electrode part is formed on the 1-2 sub gate electrode 243 is illustrated, but this is not limited thereto, and the 1-1 sub gate electrode 241 and the 1-2 sub gate electrode can each include a plurality of electrode parts and can be arranged alternately along the first direction X.

FIG. 9B is a schematic plan view of a thin film transistor substrate that briefly illustrates the formation of a channel part and a first sub channel part 220 in FIG. 9A. As can be seen in FIG. 9B, the active layer 120 includes a channel part 121, a first connection part 123, a second connection part 125, and a first sub channel part 220. According to another embodiment of the present disclosure, the first sub channel part 220 includes a 1-1 sub channel part 221a, a 1-2 sub channel part 223, and a 1-3 sub channel part 221b. The 1-1 sub channel part 221a and the 1-3 sub channel part 221b overlap with the 1-1 sub gate electrode (see 241 of FIG. 9A), and the 1-2 sub channel part 223 overlaps with the 1-2 sub gate electrode (see 243 of FIG. 9A), so that the 1-2 sub channel part can be a region that maintains semiconductor characteristic without being imparted with a conductive characteristic in the conductorized process.

In addition, the 1-1 sub channel part 221a and the 1-3 sub channel part 221b constitute a portion of the upper side of the active layer 120, and can be formed spaced apart from the lower side of the active layer 120 by a first distance d1 or a third distance d3, respectively. In this situation, the first distance d1 and the third distance d3 can be the same or different. The 1-2 sub channel part 223 and the 1-3 sub channel part 221b can be formed spaced apart from each other by the second width W2. By adjusting the first width W1, the second width W2, the first distance d1, the second distance d2, and the third distance d3 of the first sub channel part 220, the overall resistance of the first connection part 123 can be adjusted. Also, by relatively increasing the resistance of the first connection part 123 by the first sub channel part 220, when the thin film transistor substrate is in a non-driven (turn-off) state, the voltage distributed and applied to one side and the other side of the channel part 121 can be relatively lowered. Accordingly, when the voltage applied to one side and the other side of the channel part 121 in the non-driven state is relatively lowered, the trapping of charges in the channel part 121 can be prevented or minimized.

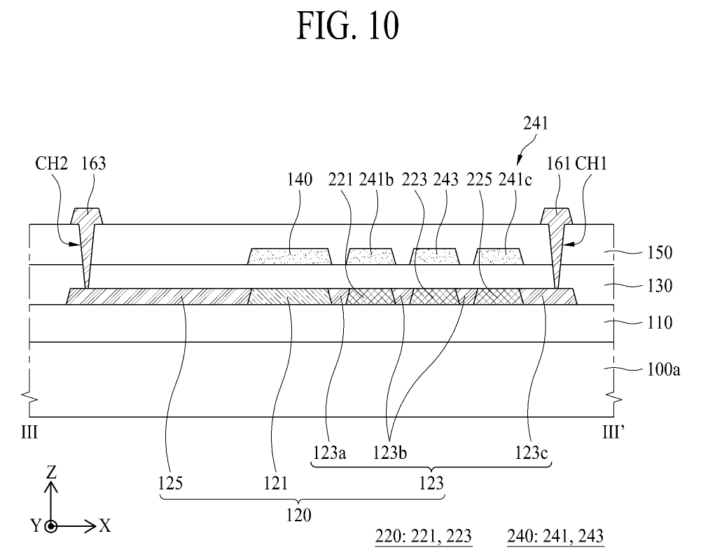

FIG. 10 is a cross-sectional view of a thin film transistor substrate according to another embodiment of the present disclosure. In particular, FIG. 10 relates to cross-section III-III' of FIG. 9A. Because the embodiment of FIG. 10 is identical to the embodiment of FIG. 5 except for the configuration of the first sub gate electrode 240, the following description will focus on the different configuration. As can be seen in FIG. 10, a thin film transistor substrate according to another embodiment of the present disclosure comprises a first substrate 100a, a buffer layer 110, an active layer 120, a gate insulating layer 130, a gate electrode 140, an interlayer insulating layer 150, a source electrode 161, and a drain electrode 163.

In addition, the active layer 120 comprises the channel part 121, the first connection part 123, the second connection part 125, and the first sub channel part 220. The first sub channel part 220 includes the 1-1 sub channel part 221a, the 1-2 sub channel part 223, and the 1-3 sub channel part 221c which are formed spaced apart from each other, and the resistance of the second region 123b of the first connection part 123 can be controlled by the 1-1 sub channel part 221a, the 1-2 sub channel part 223, and the 1-3 sub channel part 221c. The first sub gate electrode 240 includes the 1-1a electrode portion 241b, the 1-2 sub gate electrode 243, and the 1-1b electrode portion 241c, and the 1-1a electrode portion 241b, the 1-2 sub gate electrode 243, and the 1-1b electrode portion 241c can correspond to the 1-1 sub channel part 221a, the 1-2 sub channel part 223, and the 1-3 sub channel part 221c, respectively.

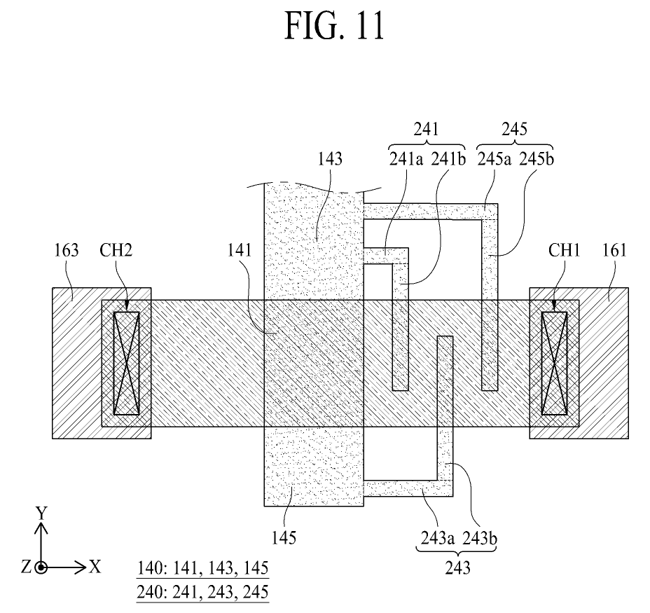

FIG. 11 is a plan view of a thin film transistor substrate according to another embodiment of the present disclosure. Because the embodiment of FIG. 11 is identical to the embodiment of FIG. 3 except for the configuration of the first sub gate electrode, the following description will focus on the different configuration. As can be seen in FIG. 11, the first sub gate electrode 240 includes a 1-1 sub gate electrode 241 and a 1-3 sub gate electrode 245 disposed in the second portion 143 of the gate electrode 140, and a 1-2 sub gate electrode 243 disposed in the third portion 145 of the gate electrode 140. The 1-3 sub gate electrode 245 includes a 1-3 extension portion 245a extending in the first direction X from the second portion 143 of the gate electrode 140 and a 1-3 electrode portion 245b extending in the second direction Y from one end of the 1-3 extension portion 245a.

In addition, the 1-3 extension portion 245a can extend from one side of the gate electrode 140, for example, the right side, so that the distance between the one side of the gate electrode 140 and the 1-3 electrode portion 245b becomes a first length L1. The 1-3 electrode portion 245b can be disposed to extend from one side of the 1-3 extension portion 245a and cover a portion of the active layer 120. In more detail, the 1-3 electrode portion 245b can be disposed to overlap with a portion of one side of the active layer 120, for example, a portion of the right side, and the 1-3 electrode portion 245b can extend along the second direction Y while overlapping with the upper side of the active layer 120 and not overlapping with the lower side of the active layer 120. By being formed in this method, the 1-3 sub gate electrode 245 can be disposed to overlap with the upper side of the active layer 120 on a plane while being spaced apart from the lower side of the active layer 120 by a first distance d1. Accordingly, the 1-3 sub gate electrode 245 may not cross the active layer 120 in the second direction Y.

According to another embodiment of the present disclosure, the 1-1 sub gate electrode 241 and the 1-3 sub gate electrode 245 are formed to be spaced apart from each other, and the 1-1 electrode portion 241b of the 1-1 sub gate electrode 241, the 1-2 electrode portion 243b of the 1-2 sub gate electrode 243, and the 1-3 electrode portion 245b of the 1-3 sub gate electrode 245 can be alternately arranged along the first direction X. By forming in this way, the resistance of the first connection part 123 of the active layer 120 can be relatively increased.

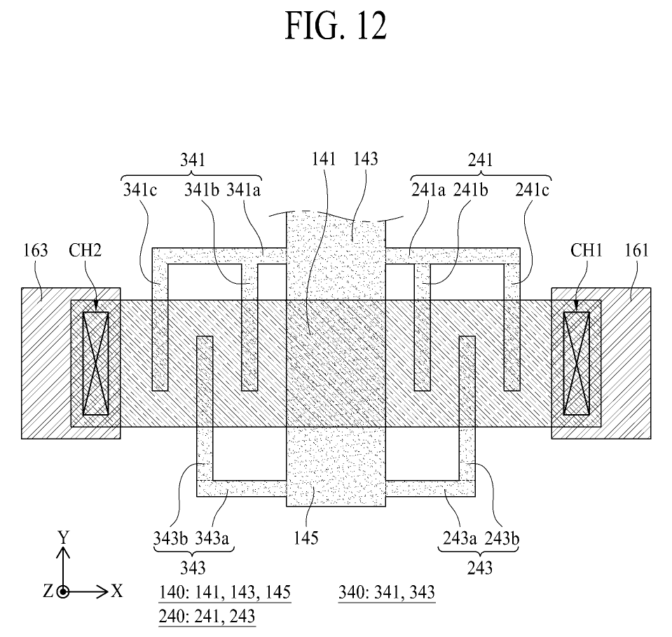

FIG. 12 is a plan view of a thin film transistor substrate according to another embodiment of the present disclosure. Because the embodiment of FIG. 12 is identical to the embodiment of FIG. 9A except for the configuration of the second sub gate electrode, the following description will focus on the different configuration. As can be seen in FIG. 12, a thin film transistor substrate according to another embodiment of the present disclosure comprises an active layer 120, a gate electrode 140, a first sub gate electrode 240, a second sub gate electrode 340, a source electrode 161, and a drain electrode 163. The second sub gate electrode 340 includes a 2-1 sub gate electrode 341 that protrudes and extends from the second portion 143 of the gate electrode 140 and a 2-2 sub gate electrode 343 that protrudes and extends from the third portion 145 of the gate electrode 140.

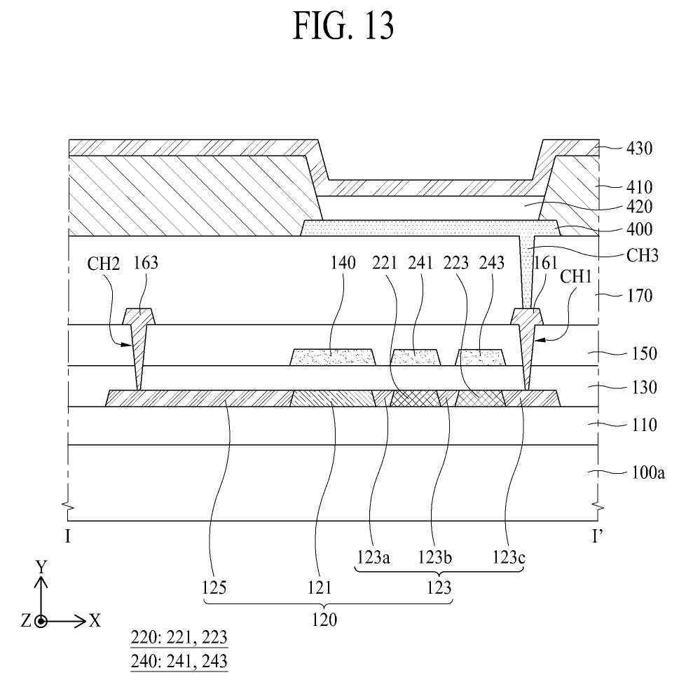

In addition, the 2-1 sub gate electrode 341 includes a 2-1 extension portion 341a extending from the other side of the gate electrode 140, a 2-1a electrode portion 341b extending and protruding from one side of the 2-1 extension portion 341a, and a 2-1b electrode portion 341c. The 2-1a electrode portion 341b, the 2-2 electrode portion 343b, and the 2-1b electrode portion 341c can be alternately disposed along the second direction X. By forming in this method, the resistance of the active layer 120, for example, the resistance of the second connection part 125, can be relatively increased. While , in FIG. 13, only the point that two electrode parts are formed on the 2-1 sub gate electrode 341 and one electrode part is formed on the 2-2 sub gate electrode 343 is illustrated, the example is not limited thereto, and the 2-1 sub gate electrode 341 and the 2-2 sub gate electrode can each include a plurality of electrode parts and can be arranged alternately along the first direction X.

FIG. 13 is a cross-sectional view of a display device including a thin film transistor substrate according to one embodiment of the present disclosure. As can be seen in FIG. 13, a display device according to one embodiment of the present disclosure includes a first substrate 100a, a buffer layer 110, an active layer 120, a gate insulating layer 130, a gate electrode 140, a first sub gate electrode 240, an interlayer insulating layer 150, a source electrode 161, a drain electrode 163, a planarization layer 170, a first electrode 400, a bank layer 410, a light emitting layer 420, and a second electrode 430. Meanwhile, the first substrate 100a, buffer layer 110, active layer 120, gate insulating layer 130, gate electrode 140, first sub gate electrode 240, interlayer insulating layer 150, source electrode 161, and drain electrode 163 are the same as those in the embodiments, so a repeated description thereof will be omitted.

Also, the planarization layer 170 can be formed on the source electrode 161 and the drain electrode 163. The planarization layer 170 is disposed with a third contact hole CH3, so that a portion of the upper surface of the source electrode 161 can be exposed through the third contact hole CH3. However, in some situations, a portion of the upper surface of the drain electrode 163 can be exposed through the third contact hole CH3.

In addition, the first electrode 400 is formed on the planarization layer 170 and is connected to the source electrode 161 or the drain electrode 163 through the fourth contact hole CH4. The first electrode 400 can function as an anode. The bank layer 410 is disposed to cover the edge of the first electrode 400 and define a light emitting area. Therefore, the upper surface area of the first electrode 400 that is exposed and not covered by the bank layer 410 becomes the light emitting area.

Further, the light emitting layer 420 can be disposed on the first electrode 400. The light emitting layer 420 can include red, green, and blue light emitting layers patterned for each pixel, or can be formed of a white light emitting layer connected to all pixels. When the light emitting layer 420 is formed of a white light emitting layer, the light emitting layer 420 can include, for example, a first stack including a blue light emitting layer, for example, a second stack including a yellow-green light emitting layer, and a charge generation layer disposed between the first stack and the second stack, but is not necessarily limited thereto. The second electrode 430 is disposed on the light emitting layer 420. The second electrode 430 can function as a cathode. In various embodiments, a sealing layer can be additionally formed on the second electrode 430 to prevent the penetration of moisture or oxygen.

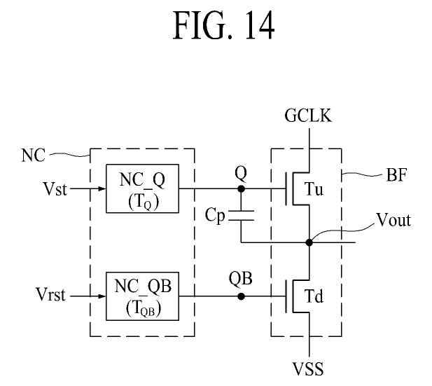

FIG. 14 is a circuit diagram of a shift register according to one embodiment of the present disclosure. As can be seen in FIG. 14, the GIP circuit is composed of a pull-up node Q, a pull-down node QB, a node control unit NC, and a buffer unit BF. The buffer section BF is connected to the output terminal and includes a pull-up transistor Tu, a pull-down transistor Td, and a capacitor Cp. The pull-up transistor Tu is turned on when the pull-up node Q is charged to a gate high voltage and outputs the gate-on signal of the gate shift clock GCLK as a gate signal Vout. The pull-down transistor Td is turned on when the pull-down node QB is charged to a gate low voltage and outputs the gate off signal as a gate signal Vout. At least one of the pull-up transistor Tu and the pull-down transistor Td can be formed of any of the various thin film transistors described above. The capacitor Cp serves to maintain the gate high voltage supplied to the gate terminal of the pull-up transistor Tu for one frame, and is disposed between the gate terminal and the source or drain terminal of the pull-up transistor Tu.

In operation, the node control unit NC controls charging and discharging of the pull-up node Q and the pull-down node QB. Such a node control unit NC can include a pull-up node control unit NC_Q for controlling charging and discharging of the pull-up node Q and a pull-down node control unit NC_QB for controlling charging and discharging of the pull-down node QB. The pull-up node control unit NC_Q includes at least one transistor TQ for controlling the pull-up node Q, and the pull-down node control unit NC_QB includes at least one transistor TQB for controlling the pull-down node QB.

Also, the output of the gate signal Vout can be stably controlled by the node control unit NC. In detail, the node control unit NC discharges the pull-down node QB to a gate low voltage when the pull-up node Q is charged to a gate high voltage, and discharges the pull-up node Q to a gate low voltage when the pull-down node QB is charged to a gate high voltage. Accordingly, when a gate start signal Vst is applied, the pull-up node Q is charged to a gate high voltage and the pull-down node QB is discharged to a gate low voltage by the operation of the plurality of transistors TQ, TQB disposed in the node control unit NC to output the gate on signal of the gate shift clock GCLK as a gate signal Vout. In addition, when a gate reset signal Vrst is applied, the pull-up node Q is discharged to a gate low voltage and the pull-down node QB is charged to a gate high voltage by the operation of the plurality of transistors TQ, TQB disposed in the node control unit NC to output the low power voltage VSS as a gate signal Vout. At least one of the plurality of transistors TQ, TQB disposed in the node control unit NC can be formed of any of the various thin film transistors described above.

Although the embodiments of the present disclosure have been described in more detail with reference to the attached drawings, the present disclosure is not necessarily limited to these embodiments, and various modifications can be made without departing from the technical idea of the present disclosure. Accordingly, the embodiments disclosed in the present disclosure are not intended to limit the technical idea of the present disclosure, but to explain it, and the scope of the technical idea of the present disclosure is not limited by these embodiments. Therefore, it should be understood that the embodiments described above are exemplary in all aspects and not restrictive. The protection scope of the present disclosure should be interpreted by the claims, and all technical ideas within a scope equivalent thereto should be interpreted as being included in the scope of the rights of the present disclosure.

According to the present disclosure as described above, the following effects are achieved. According to one embodiment of the present disclosure, when a thin film transistor substrate is not driven by at least two sub channel parts disposed in a conductive connection portion of an active layer, the resistance of the conductive connection portion is increased to lower the magnitude of the voltage distributed and applied to the channel part, thereby implementing a device with improved reliability. According to one embodiment of the present disclosure, even if a high voltage is continuously applied to a source or drain electrode in an undriven state, the voltage distributed to one side and the other side of the channel part is relatively low, so that charges can be prevented from being trapped in the channel part of the active layer in an undriven state.

According to one embodiment of the present disclosure, when the thin film transistor substrate is driven, current can flow through the sub channel part by the electric field formed by the sub gate electrode, so that a thin film transistor substrate in which the on-current characteristic is not deteriorated can be implemented. The effects of the present disclosure are not limited to the effects mentioned above, and other effects not mentioned will be clearly understood by those skilled in the art from the description below.

What is claimed is:

1. A thin film transistor substrate comprising:
a substrate;
an active layer on the substrate;
a gate electrode overlapping the active layer;
a first sub gate electrode electrically connected to the gate electrode and overlapping the active layer at one side of the gate electrode in plain view; and
a second sub gate electrode electrically connected to the gate electrode and overlapping the active layer at an other side of the gate electrode in plan view,
wherein the one side of the gate electrode opposed the other side opposing the one side of the gate electrode in plan view, and
wherein the first sub gate electrode and the second sub gate electrode are spaced apart from the active layer.

2. The thin film transistor substrate of claim 1, wherein the first sub gate electrode and the second sub gate electrode are spaced apart from the gate electrode in a region overlapping the active layer.

3. The thin film transistor substrate of claim 1, wherein the gate electrode completely crosses the active layer,
wherein the first sub gate electrode does not completely cross the active layer, and
wherein the second sub gate electrode does not completely cross the active layer.

4. The thin film transistor substrate of claim 1, wherein the gate electrode, the first sub gate electrode, and the second sub gate electrode receive the same voltage.

5. The thin film transistor substrate of claim 1, wherein the first sub gate electrode includes a first extension portion protruding from the gate electrode and a first electrode portion overlapping the active layer,
wherein the second sub gate electrode includes a second extension portion protruding from the gate electrode and a second electrode portion overlapping the active layer, and
wherein the first extension portion and the second extension portion are disposed outside the active layer in plan view.

6. The thin film transistor substrate of claim 5, wherein the first extension portion is disposed adjacent to an upper side of the active layer, and
wherein the second extension portion is disposed adjacent to a lower side of the active layer.

7. The thin film transistor substrate of claim 1, wherein the active layer includes a channel part, a first connection part disposed on one side of the channel part, and a first sub channel part and a second sub channel part disposed to surround the first connection part, and
wherein the first sub channel part and the second sub channel part are spaced apart from each other.

8. The thin film transistor substrate of claim 7, wherein the gate electrode, the first sub gate electrode, or the second sub gate electrode receives the same voltage, and
wherein a current flows across the channel part, the first sub channel part, and the second sub channel part.

9. The thin film transistor substrate of claim 7 further comprising:
a gate insulating layer on the active layer,
wherein the gate insulating layer is disposed under the gate electrode and the first sub gate electrode, and
wherein the gate insulating layer includes a first portion corresponding to one end and the other end of the gate electrode, and a second portion corresponding to one end and the other end of the first sub gate electrode.

10. The thin film transistor substrate of claim 1 further comprising:
a third sub gate electrode disposed on the active layer and disposed on the one side of the gate electrode,
wherein the third sub gate electrode overlaps the one side of the active layer and is spaced apart from the other side of the active layer in a planar view, and
wherein the third sub gate electrode is spaced apart from the first sub gate electrode and the second sub gate electrode in a region overlapping the active layer.

11. The thin film transistor substrate of claim 10, wherein the first sub gate electrode is disposed between the second sub gate electrode and the third sub gate electrode.

12. The thin film transistor substrate of claim 10, wherein the active layer includes a channel part, a first connection part on one side of the channel part, and a first sub channel part, a second sub channel part, and a third sub channel part disposed to surround the first connection part, and
wherein the first to third sub channel parts are spaced apart from each other.

13. The thin film transistor substrate of claim 12, wherein the first sub channel part is disposed between the second sub channel part and the third sub channel part.

14. The thin film transistor substrate of claim 1 further comprising:
a fourth sub gate electrode and a fifth sub gate electrode disposed on the active layer and disposed on the other side of the gate electrode, and
wherein the fourth sub gate electrode and a fifth sub gate electrode overlap the active layer in plan view.

15. A display device comprising:
a display panel; and
a thin film transistor substrate including:
a substrate;
an active layer on the substrate;
a gate electrode overlapping the active layer;
a first sub gate electrode electrically connected to the gate electrode and overlapping the active layer at one side of the gate electrode in plain view; and
a second sub gate electrode electrically connected to the gate electrode and overlapping the active layer at an other side of the gate electrode in plan view,
wherein the one side of the gate electrode opposed the other side opposing the one side of the gate electrode in plan view, and
wherein the first sub gate electrode and the second sub gate electrode are spaced apart from the active layer.

16. A thin film transistor substrate comprising:
a substrate;
an active layer on the substrate;
a gate electrode completely crossing the active layer and having one side overlapping the active layer and an other side opposing the one side and overlapping the active layer;
a first sub gate electrode electrically connected to the gate electrode and overlapping the active layer in plan view; and
a second sub gate electrode electrically connected to the gate electrode and overlapping the active layer in plan view,
wherein the first sub gate electrode and the second sub gate electrode are spaced apart from the active layer,
wherein the first sub gate electrode does not completely cross the active layer, and
wherein the second sub gate electrode does not completely cross the active layer.

17. The thin film transistor substrate of claim 16, wherein the first sub gate electrode and the second sub gate electrode are spaced apart from, and extend parallel too, the gate electrode in a region overlapping the active layer.

18. The thin film transistor substrate of claim 17, wherein gate electrode is directly between the first sub gate electrode and the second sub gate electrode.

19. The thin film transistor substrate of claim 17, wherein the first sub gate electrode is directly between the gate electrode and the second sub gate electrode.

20. The thin film transistor substrate of claim 17, wherein the active layer includes a channel part directly below the gate electrode, a first sub channel part directly below the first sub gate electrode, and a second sub channel part directly below the second sub gate electrode in plan view, and
wherein the channel part, the first sub channel part, and the second sub channel part are spaced apart from each other.
